(19) United States
(12) Patent Application Publication
(10) Pub. No.: US 2022/0223463 A1
(43) Pub. Date: Jul. 14, 2022

(54) DEPOSITION APPARATUS AND DEPOSITION METHOD

(71) Applicant: Tokyo Electron Limited, Tokyo (JP)

(72) Inventors: Hitoshi KATO, Iwate (JP); Toshiyuki NAKATSUBO, Iwate (JP)

(21) Appl. No.: 17/644,412

(22) Filed: Dec. 15, 2021

(30) Foreign Application Priority Data
Jan. 13, 2021 (JP) 2021-003756

(51) Int. Cl. H01L 21/687; H01J 37/32; C23C 16/458; C23C 16/44

(52) U.S. Cl. CPC H01L 21/68785; H01L 21/68771; H01J 37/32449; H01L 21/02164; C23C 16/4408; C23C 16/4585; C23C 16/4584

(57) ABSTRACT

A deposition apparatus includes a processing chamber, and a susceptor provided in the processing chamber. The susceptor has a recess on a surface of the susceptor. The recess includes a support and a groove, the support supports a region that includes a center of a substrate and that does not include an edge of the substrate, the groove is located around the support, and the groove is recessed relative to the support. The deposition apparatus further includes a process gas supply configured to supply a process gas to the surface of the susceptor and a purge gas supply configured to supply a purge gas to the groove.

### CROSS-REFERENCE TO RELATED APPLICATIONS

This patent application is based on and claims priority to Japanese Patent Application No. 2021-003756 filed on Jan. 13, 2021, the entire contents of which are incorporated herein by reference.

### TECHNICAL FIELD

The present disclosure relates to a deposition apparatus and a deposition method.

### BACKGROUND

In a substrate processing apparatus that performs a process by supplying a process gas to a wafer while causing the wafer mounted on a susceptor in a processing chamber to revolve, a configuration in which a recess for mounting the wafer on the surface of the susceptor is provided is known (see, for example, Patent Document 1). In the substrate processing apparatus, a stage that supports the center of the wafer from a lower side is provided in the recess, and a circumferential edge portion of the wafer floats from the bottom of the recess.

### RELATED ART DOCUMENT

### Patent Document

[Patent Document 1] Japanese Laid-open Patent Application Publication No. 2013-222948

### SUMMARY

According to one aspect of the present disclosure, a deposition apparatus includes a processing chamber, and a susceptor provided in the processing chamber. The susceptor has a recess on a surface of the susceptor. The recess includes a support and a groove, the support supports a region that includes a center of a substrate and that does not include an edge of the substrate, the groove is located around the support, and the groove is recessed relative to the support. The deposition apparatus further includes a process gas supply configured to supply a process gas to the surface of the susceptor and a purge gas supply configured to supply a purge gas to the groove.

### BRIEF DESCRIPTION OF THE DRAWINGS

FIG. 1 is a cross-sectional view illustrating an example of a deposition apparatus according to an embodiment;

FIG. 2 is a horizontal cross-sectional view of the deposition apparatus in FIG. 1;

FIG. 3 is a horizontal cross-sectional view of the deposition apparatus in FIG. 1;

FIG. 4 is a perspective view illustrating a portion of an interior of the deposition apparatus in FIG. 1;

FIG. 5 is a plan view illustrating an example of a susceptor of the deposition apparatus in FIG. 1;

FIG. 6 is a drawing illustrating an enlarged recess of the receptor of FIG. 5;

FIG. 7 is a drawing illustrating a cross-section cut along a dash-dot-dash line IIV-IIV in FIG. 6;

FIG. 8 is an enlarged view of a region A1 in FIG. 7;

FIG. 9 is an enlarged view of a region A2 in FIG. 7;

FIG. 10 is a cross-sectional view illustrating a function of a conventional susceptor;

FIG. 11 is a cross-sectional view illustrating the function of the conventional susceptor;

FIG. 12 is a cross-sectional view illustrating the function of the conventional susceptor;

FIG. 13 is a cross-sectional view illustrating the function of the conventional susceptor;

FIG. 14 is a graph for describing a film deposited on a wafer when using the conventional susceptor;

FIG. 15 is a cross-sectional view illustrating another example of the susceptor of the deposition apparatus of FIG. 1; and

FIG. 16 is a flow chart illustrating an example of a deposition method of the embodiment.

### DETAILED DESCRIPTION OF EMBODIMENTS

According to the present disclosure, deposition on a back surface edge portion of a substrate can be suppressed.

In the following, an embodiment, which is a non-restrictive example, of the present disclosure will be described with reference to the accompanying drawings. In all the accompanying drawings, the same or corresponding reference numerals will be used to refer to the same or corresponding members or parts and the overlapped description will be omitted.

[Deposition Apparatus]

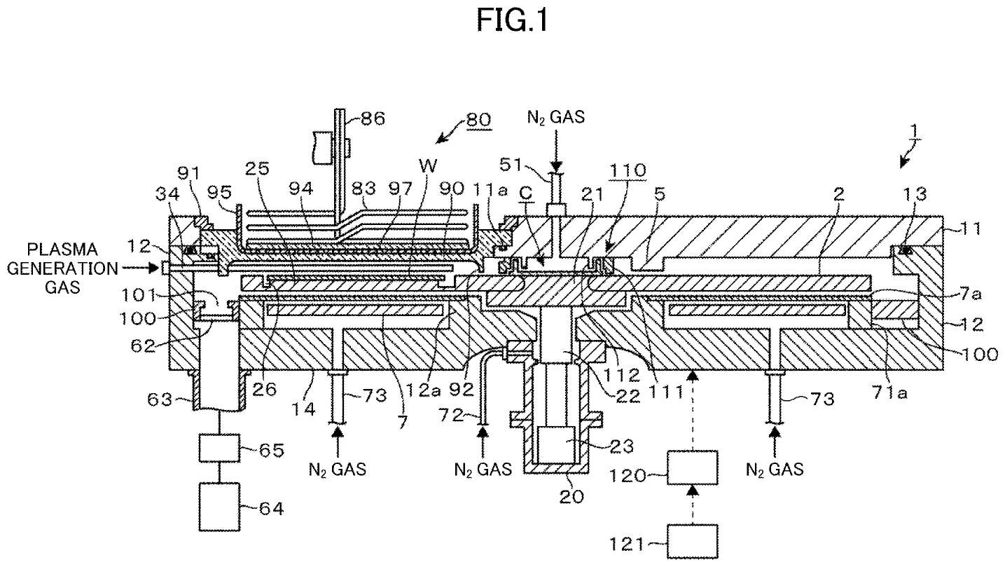

An example of a deposition apparatus according to an embodiment will be described with reference to FIGS. 1 to 4. The deposition apparatus according to the embodiment includes a processing chamber 1 having a substantially circular shape as a plane shape and a susceptor 2 that is provided in the processing chamber 1 and that has a center of rotation at the center of the processing chamber 1. The deposition apparatus is configured as an apparatus that performs a deposition process on a substrate (for example, a wafer W). In the following, each part of the deposition apparatus will be described.

The processing chamber 1 is a vacuum chamber that can decompress the inside. The processing chamber 1 includes a top plate 11 and a chamber body 12. The top plate 11 is removably attached to the chamber body 12 through a seal member 13. A separation gas supply line 51 is provided at the center in the upper surface of the top plate 11. The separation gas supply line 51 supplies a nitrogen (N₂) gas as a separation gas in order to suppress mixing of different process gases in a central region C in the processing chamber 1.

A heater 7 is provided above a bottom 14 of the processing chamber 1 (FIG. 1). The heater 7 heats the wafer W on the susceptor 2 to the deposition temperature (e.g., 300° C.) through the susceptor 2. A cover member 71a is provided at the side of the heater 7, and a cover member 7a that covers the heater 7 is provided above the heater 7. On the bottom 14 below the heater 7, multiple purge gas supply lines 73 are provided over a circumferential direction to purge a space in which the heater 7 is provided.

The susceptor 2 is fixed to a core 21 that has a substantially cylindrical shape, at the center of the susceptor 2. The susceptor 2 is configured to rotate clockwise about the vertical axis in this example, by a rotating shaft 22 that is connected to the lower surface of the core 21 and that extends in the vertical direction. The rotating shaft 22 is rotated about the vertical axis by a drive section 23. The rotating shaft 22 and the drive section 23 are accommodated in a case body 20. An upper flange of the case body 20 is airtightly attached to the lower surface of the bottom 14 of the processing chamber 1. Additionally, a purge gas supply line 72 is connected to the case body 20 for supplying the N₂ gas as the purge gas to a lower region of the susceptor 2. The bottom 14 of the processing chamber 1 is annularly formed at the outer circumferential side of the core 21 to come closer to the lower side of the susceptor 2 to form a protrusion 12a.

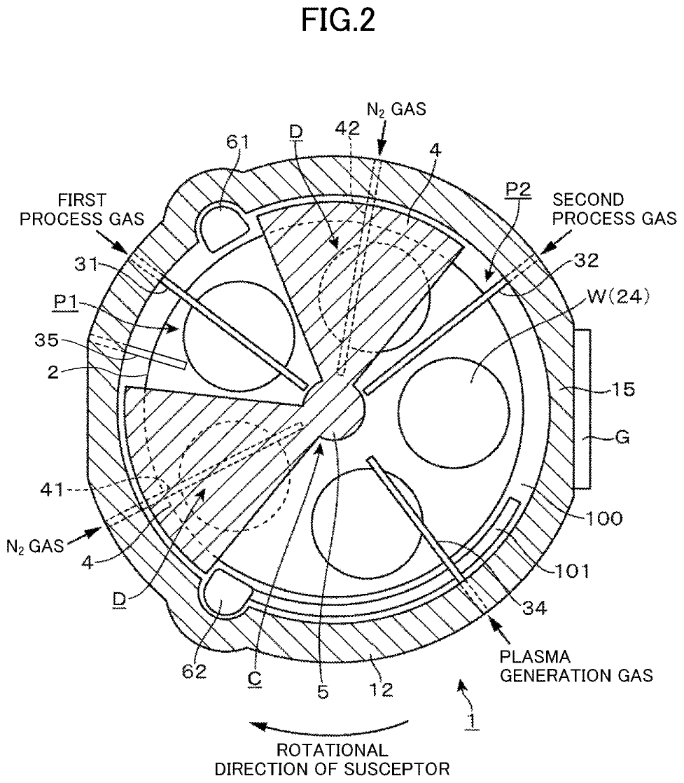

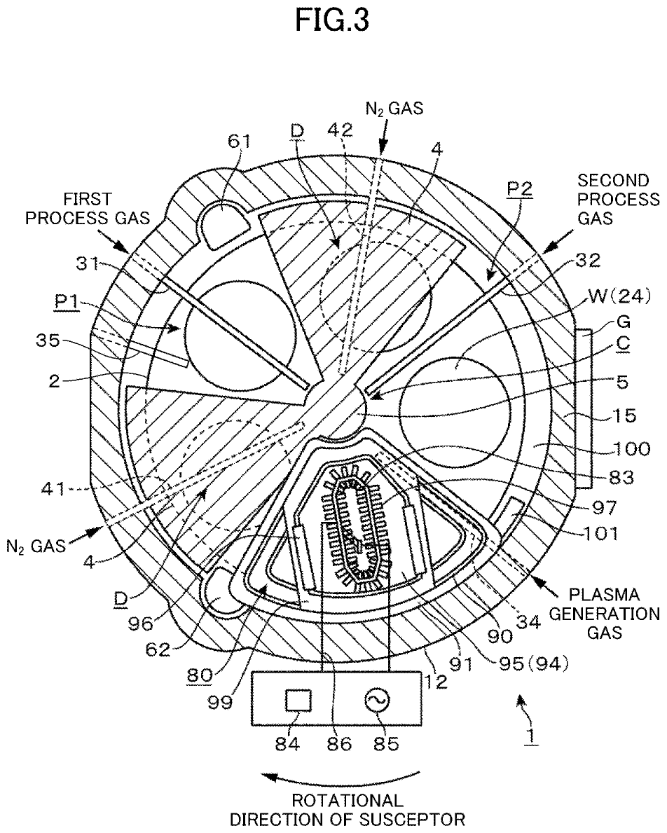

A recess 24 is provided on the surface of the susceptor 2. The recess 24 has a circular shape in a plan view and holds the wafer W with the wafer W being dropped in the recess 24. The wafer W may be, for example, a silicon wafer having a circular plate shape (a circular shape). The recesses 24 are formed at multiple locations along the direction of rotation (the circumferential direction) of the susceptor 2. In the examples of FIGS. 1-4, the recesses 24 are formed at five locations along the direction of rotation (the circumferential direction) of the susceptor 2. Each recess 24 is formed such that the diameter thereof is greater than the diameter of the wafer W in a plan view in order to provide a clearance area between the outer edge thereof and the outer edge of the wafer W. The diameter of the susceptor 2 is about 1000 mm, for example. In the recess 24, through-holes 24a through which, for example, three lift pins (not illustrated) protrude and retract to move the wafer W up and down from the lower side are formed. In FIG. 2 and FIG. 3, the diameter dimensions of the recesses 24 are simplified. In FIGS. 1 to 3, the through-holes 24a are not illustrated.

At respective positions opposite to regions where the recesses 24 pass by, six nozzles 31, 32, 34, 35, 41, and 42 made of, for example, quartz are radially provided spaced from each other in the circumferential direction of the processing chamber 1. Each of the nozzles 31, 32, 34, 35, 41, and 42 is attached, for example, to extend horizontally from the outer wall surface of the processing chamber 1 toward the central region C, and to be opposite to the wafer W. In this example, a plasma generation gas nozzle 34, a separation gas nozzle 41, a cleaning gas nozzle 35, a first process gas nozzle 31, a separation gas nozzle 42, and a second process gas nozzle 32 are arranged in this order in the direction of rotation of the susceptor 2 as seen from a transfer port 15 described below. A plasma generator 80 is provided above the plasma generation gas nozzle 34 to make plasma from a gas discharged from the plasma generation gas nozzle 34. The plasma generator 80 will be described later.

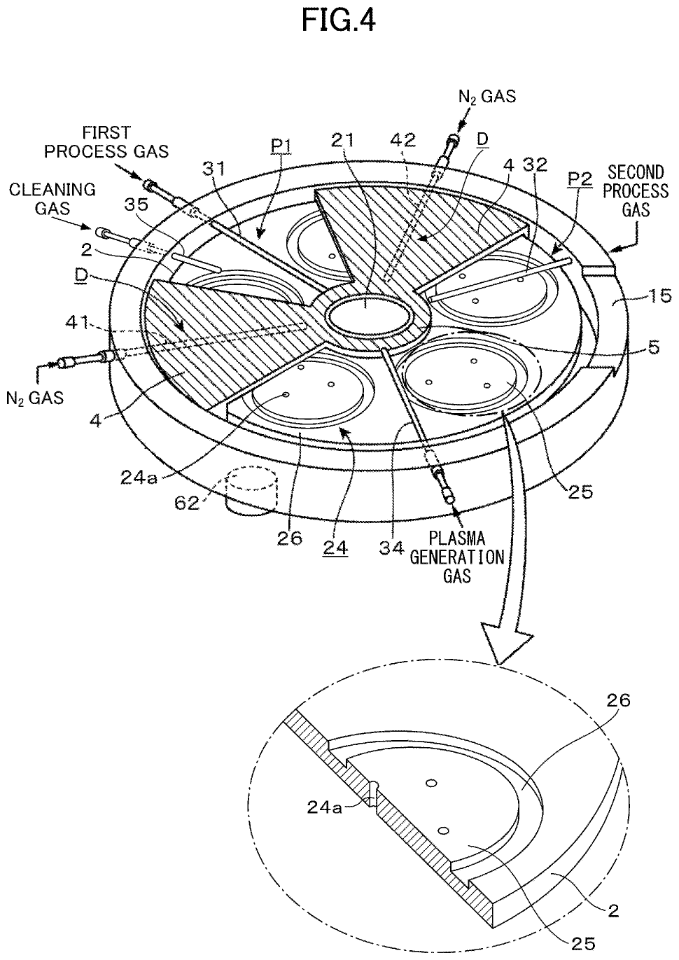

The first process gas nozzle 31 and the second process gas nozzle 32 respectively serve in a first process gas supply and a second process gas supply, the separation gas nozzles 41 and 42 respectively serve in separation gas supplies, and the cleaning gas nozzle 35 serves in a cleaning gas supply. FIG. 2 and FIG. 4 illustrate a state in which the plasma generator 80 and a housing 90 described later are detached such that the plasma generation gas nozzle 34 can be seen. FIG. 3 illustrates a state in which the plasma generator 80 and the housing 90 are attached.

The nozzles 31, 32, 34, 35, 41, and 42 are respectively connected to the following gas supply sources (not illustrated) through flow control valves. That is, the first process gas nozzle 31 is connected to a supply source of the first process gas that contains silicon (Si). The first process gas may be, for example, a BTBAS (vistar-butyl aminosilane, SiH₂ (NH—C(CH₃)₃)₂) gas. The second process gas nozzle 32 is connected to a supply source of the second process gas (e.g., a mixed gas of an ozone (O₃) gas and an oxygen (O₂) gas) (in detail, an oxygen gas source with an ozonizer). The plasma generation gas nozzle 34 is connected to a supply source of the plasma generation gas formed of, for example, a mixed gas of an argon (Ar) gas and an O₂ gas. The separation gas nozzles 41 and 42 are respectively connected to gas supply sources of an N₂ gas, which is the separation gas. At the lower surfaces of the nozzles 31, 32, 34, 41, and 42, gas discharge holes (not illustrated) are formed at multiple locations along the radial direction of the susceptor 2 to be equally spaced, for example.

The lower region of the first process gas nozzle 31 is a first process region P1 for adsorbing the first process gas onto the wafer W. The lower region of the second process gas nozzle 32 is a second process region P2 for reacting the component of the first process gas adsorbed onto the wafer W with the second process gas. The separation gas nozzles 41 and 42 respectively form separation regions D that separate the first process region P1 and the second process region P2. A convex portion 4 having an approximate fan shape as illustrated in FIG. 2 and FIG. 3 is provided on the top plate 11 of the processing chamber 1 in the separation region D, and the separation gas nozzles 41 and 42 are accommodated in the convex portions 4. Thus, at both sides of the separation gas nozzles 41 and 42 in the circumferential direction of the susceptor 2, lower ceiling surfaces that are a lower surface of the convex portion 4 are provided in order to prevent the process gases from mixing with each other, and at both sides in the circumferential direction of the ceiling surface, ceiling surfaces higher than the ceiling surface (i.e., the lower surface of the convex portion 4) are provided. A circumferential edge portion of the convex portion 4 (a portion on the outer edge side of the processing chamber 1) is bent in an L-shape so as to face the outer edge surface of the susceptor 2 and be slightly spaced from the chamber body 12 in order to prevent the process gases from mixing with each other.

Next, a plasma generator 80 will be described. The plasma generator 80 is configured by winding an antenna 83 made of a metal wire in a coil form and is disposed so as to be over the passing area of the wafer W from the central portion to the circumferential edge portion of the susceptor 2. The antenna 83 is disposed to connect, through a matcher 84, a high-frequency power supply 85 having a frequency of 13.56 MHz and output power of 5000 W, for example, and to be airtightly partitioned from the internal area of the processing chamber 1. The plasma generator 80, the matcher 84, and the high-frequency power supply 85 are electrically connected by a connection electrode 86. That is, the top plate 11 has an opening having an approximate fan shape above the plasma generation gas nozzle 34 in a plan view and is airtightly sealed by a housing 90 made of, for example, quartz. The housing 90 is formed such that the circumferential edge portion extends horizontally over the circumferential direction in a flange form and the center portion is recessed toward the internal area of the processing chamber 1, and the antenna 83 is accommodated inside the housing 90. A sealing member 11a is provided between the housing 90 and the top plate 11. The circumferential edge portion of the housing 90 is pressed downwardly by a pressing member 91.

An outer edge portion of the lower surface of the housing 90 extends vertically over the circumferential direction to the lower side (the susceptor 2 side) to form a protrusion 92 for gas control, in order to prevent the entry of the N₂ gas, the O₃ gas), or the like into the lower area of the housing 90, as illustrated in FIG. 1. The plasma generation gas nozzle 34 is accommodated in an area surrounded by the inner circumferential surface of the protrusion 92, the lower surface of the housing 90, and the upper surface of the susceptor 2.

Between the housing 90 and the antenna 83, a substantially box-shaped Faraday shield 95 having an opening upward, as illustrated in FIGS. 1 and 3, is disposed. The Faraday shield 95 is formed of a metal plate that is an electrically conductive plate and is grounded. Slits 97 formed so as to extend in a direction orthogonal to the winding direction of the antenna 83 are provided on the bottom surface of the Faraday shield 95 and are positioned at the lower position of the antenna 83 over the circumferential direction. The slit 97 prevents the electric field component of the electric field and the magnetic field (the electromagnetic field) generated at the antenna 83 from moving downward toward the wafer W and allows the magnetic field to reach the wafer W. An insulating plate 94 is interposed between the Faraday shield 95 and the antenna 83. The insulating plate 94 is formed, for example, of quartz, and insulates the Faraday shield 95 and the antenna 83.

An annular side ring 100 is disposed on the outer circumferential side of the susceptor 2 slightly below the susceptor 2. On the upper surface of the side ring 100, two exhaust ports 61 and 62 are formed to be spaced from each other in the circumferential direction. In other words, two exhaust ports are formed in the bottom 14 of the processing chamber 1, and the exhaust ports 61 and 62 are formed in the side ring 100 at positions corresponding to these exhaust ports. The exhaust port 61 is formed at a position that is between the first process gas nozzle 31 and the separation region D on the downstream side of the susceptor in the rotation direction from the first process gas nozzle 31 and that is closer to the separation region D. The exhaust port 62 is formed at a position that is between the plasma generation gas nozzle 34 and the separation region D on the downstream side of the susceptor in the rotation direction from the plasma generation gas nozzle 34 and that is closer to the separation region D.

The exhaust port 61 is for exhausting the first process gas and the separation gas, and the exhaust port 62 is for exhausting the plasma generation gas in addition to the second process gas and the separation gas. Additionally, the exhaust port 62 exhausts the cleaning gas during cleaning. A gas flow path 101 having a groove shape is formed on the upper surface of the side ring 100 on the outer edge side of the housing 90 for allowing gas to flow through the exhaust port 62 while flowing around the housing 90. As illustrated in FIG. 1, the exhaust ports 61 and 62 are connected to a vacuum pump 64 that is a vacuum exhaust mechanism, for example, through exhaust piping 63, such as butterfly valves, in which a pressure adjuster 65 is provided between the exhaust ports 61 and 62 and the vacuum pump 64.

In the center in the lower surface of the top plate 11, as illustrated in FIG. 2, a protrusion 5 is provided. The protrusion 5 is formed in a substantially annular shape over the circumferential direction that continues from a portion of the central region C of the convex portion 4 and is formed such that the lower surface of the protrusion 5 is at the same height as the lower surface of the convex portion 4. A labyrinth structure 110 is provided above the core 21 on the side of the center of rotation of the susceptor 2 from the protrusion 5 to prevent the first process gas and the second process gas from mixing with each other in the central region C. The labyrinth structure 110 has a structure in which a first wall 111 extending vertically from the susceptor 2 side toward the top plate 11 side over the circumferential direction and a second wall 112 extending vertically from the top plate 11 side to the susceptor 2 over the circumferential direction are alternately disposed in the radial direction of the susceptor 2.

On the side wall of the processing chamber 1, a transfer port 15 is formed for transferring the wafer W between an external transfer arm (not illustrated) and the susceptor 2, as illustrated in FIG. 2 and FIG. 3. The transfer port 15 is airtightly opened and closed by a gate valve G. A lift pin (not illustrated) is provided on the lower side of the susceptor 2 at a position facing the transfer port 15. The lift pin lifts the wafer W from the back side through the through-hole 24a of the susceptor 2.

The deposition apparatus includes a controller 120 formed of a computer that controls an operation of the entire apparatus. A memory of the controller 120 stores a program for performing a deposition method described later. The program includes a group of steps for performing an operation of the apparatus described later and is installed in the controller 120 from a storage unit 121 that is a storage medium such as a hard disk drive, a compact disk, an optical disk, a memory card, or a flexible disk.

<Susceptor Structure>

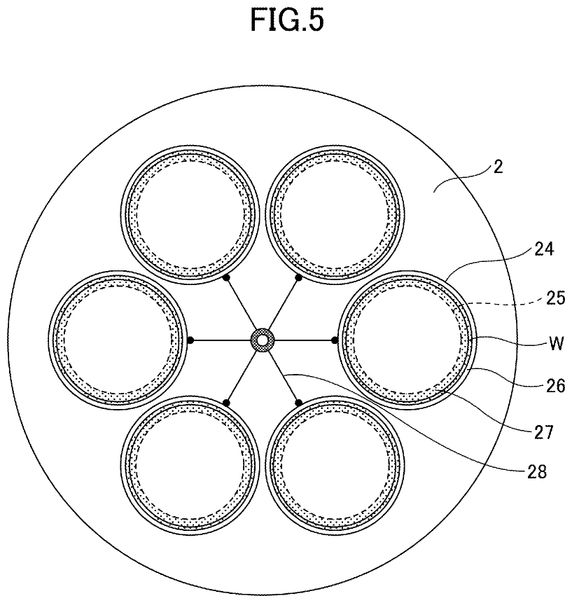

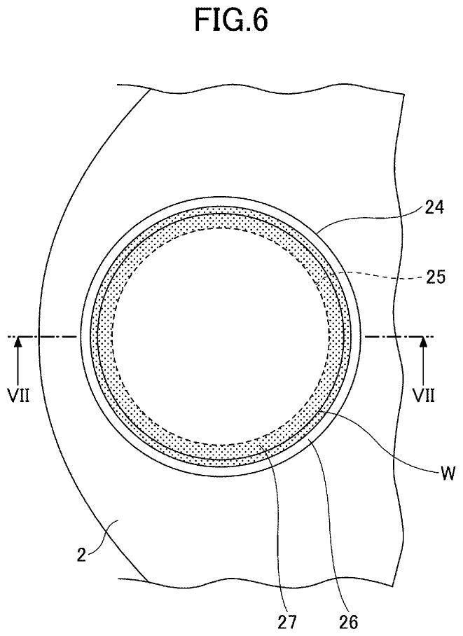

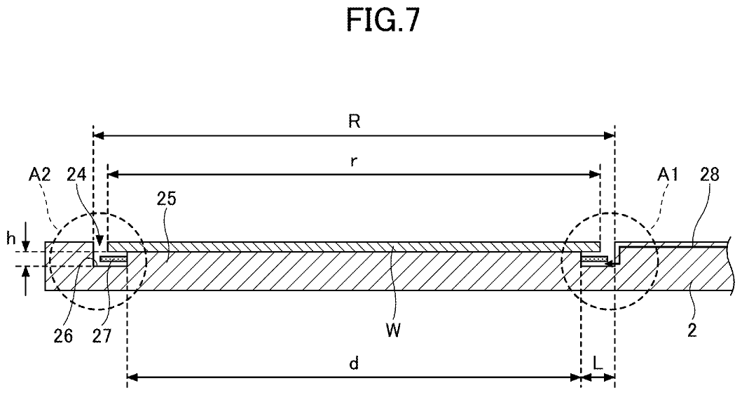

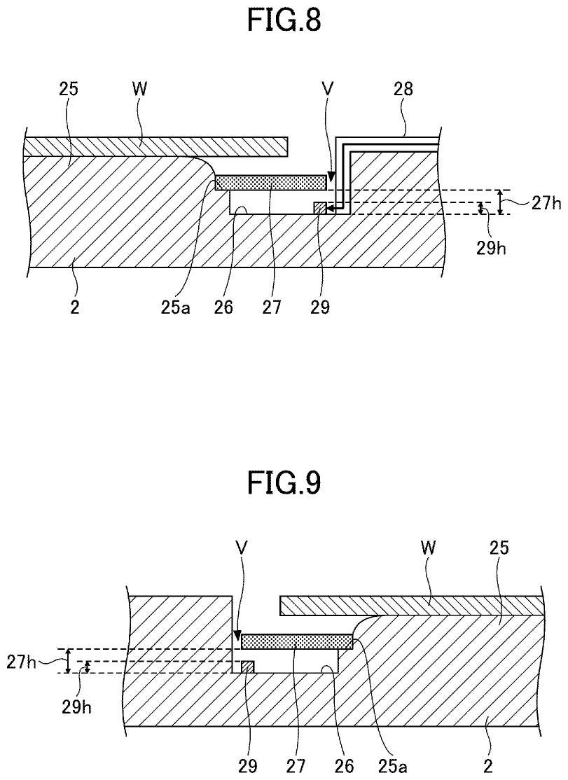

An example of the susceptor 2 of the deposition apparatus according to the embodiment will be described with reference to FIGS. 5 to 9.

The susceptor 2 is formed, for example, of quartz. The susceptor 2 is fixed to the core 21 having a substantially cylindrical shape, at the center of the susceptor 2, as described above. The susceptor 2 is configured to rotate clockwise about the vertical axis in this example, by the rotating shaft 22 that is connected to the lower surface of the core 21 and that extends in the vertical direction (FIGS. 1 to 4).

The susceptor 2 includes the recess 24, a support 25, a groove 26, a porous ring 27, the purge gas supply 28, and an annular protrusion 29.

The recesses 24 are formed at multiple locations (six locations in FIG. 5) along the direction of rotation (the circumferential direction) of the susceptor 2. Each recess 24 has a circular shape. Each recess 24 is formed such that the diameter thereof is greater than the diameter of the wafer W in a plan view in order to provide a clearance area between the outer edge thereof and the outer edge of the wafer W. In one embodiment, a diameter size r of the wafer is 300 mm and a diameter size R of the recess is 302 mm.

The support 25 is provided on the bottom surface of each recess 24. The support 25 supports the center of the wafer W from the lower side. The support 25 is configured to have a cylindrical shape and have a horizontal surface on the top. The support 25 is formed to be in the shape of a smaller circle than the wafer W in a plan view so that a circumferential edge portion of the wafer W floats from the bottom surface of the recess 24 in the circumferential direction, i.e. the circumferential edge portion does not touch the support 25 (protruded from the support 25). Thus, the support 25 is formed such that when the wafer W is mounted on the support 25, the circumferential edge portion of the wafer W faces the bottom surface of the recess 24 over the circumferential direction.

A height h of the support 25 is set such that the surface of the wafer W and the surface of the susceptor 2 are aligned, for example, when the wafer W is mounted on the support 25. In one embodiment, the height h of the support 25 is about 0.03 mm to 0.2 mm, and a diameter d of the support 25 is 297 mm.

The groove 26 is formed around the support 25, and more specifically, is formed between an inner wall surface of the recess 24 and an outer wall surface of the support 25. The groove 26 has an annular shape. The support 25 is disposed in the center of the recess 24 in a plan view. That is, the center position of the support 25 and the center position of the recess 24 match in a plan view. Thus, a width L of the groove 26 is constant over the circumferential direction in a plan view. In one embodiment, the width L of the groove 26 is 2.5 mm.

The porous ring 27 is disposed at the circumferential edge portion of the support 25 between the back surface of the wafer W supported by the support 25 and the bottom surface of the groove 26. The porous ring 27 has an annular shape. In one embodiment, the porous ring 27 is disposed such that an inner edge of the porous ring 27 is on a step 25a formed on the outer wall surface of the support 25 and there is a clearance V between the inner wall surface of the recess 24 and the porous ring 27. The porous ring 27 is formed of, for example, a porous material, such as SiC, SiN, or the like.

The purge gas supply 28 supplies the purge gas to the groove 26. In one embodiment, the purge gas supply 28 includes a gas flow path that radially extends from the central region C in the processing chamber 1 to the groove 26 formed in each recess 24 (FIG. 5). The purge gas supply 28 may be, for example, a flow path through which the separation gas supplied from the separation gas supply line 51 to the central region C in the processing chamber 1 is directed to the groove 26 formed in each recess 24. The purge gas supplied to the groove 26 is supplied to the back surface of the wafer W through the porous ring 27. This can suppress the floating of the wafer W caused by the purge gas because the flow rate of the purge gas can be suppressed and the purge gas can be widely and evenly supplied. The purge gas supply 28 supplies the purge gas to the groove 26 when the process gas is supplied to the surface of the susceptor 2 in a state where the wafer W is mounted on the support 25, for example. The purge gas supplied to the groove 26 prevents the process gas from contacting a back surface edge portion of the wafer W, the inner wall surface of the groove 26, the bottom surface of the groove 26, and the like. Thus, the deposition on the back surface edge portion of the wafer W, the inner wall surface of the groove 26, the bottom surface of the groove 26, and the like is suppressed. As a result, particles generated in the grooves 26 by the accumulation of the deposited films can be reduced, thereby improving throughput yield. Additionally, because the deposition on the back surface edge portion of the wafer W can be suppressed, the time of the process of etching and removing the film deposited on the back surface edge portion of the wafer W can be reduced or removed, thereby improving productivity. Further, because the deposition on the groove 26 is suppressed, the time of dry cleaning to remove the films deposited on the susceptor 2 can be reduced, thereby reducing the time in which the susceptor 2 is exposed to the etching gas and extending the life of the susceptor 2. As a result, the cost associated with replacing the susceptor 2 can be reduced. In addition, the maintenance cycle can be extended, thereby improving productivity.

In one embodiment, the purge gas supply 28 starts supplying of the purge gas to the groove 26 before starting supplying the process gas to the surface of the susceptor 2, and stops supplying of the purge gas to the groove 26 after stopping supplying the process gas to the surface of the susceptor 2. The purge gas supply 28 may be formed, for example, by making holes in the interior of the susceptor 2 or by providing a groove on the surface of the susceptor 2.

The annular protrusion 29 is provided along the groove 26. The annular protrusion 29 has a circular shape in a plan view and protrudes from the bottom surface of the groove 26. In one embodiment, the annular protrusion 29 has a height 29h that is less than a height 27h of the lower surface of the porous ring 27 relative to the bottom surface of the groove 26. The annular protrusion 29 distributes the purge gas supplied from the purge gas supply 28 from the inner wall surface side of the recess 24 toward the outer wall surface side of the support 25 in the circumferential direction of the groove 26. This allows the purge gas supplied from the purge gas supply 28 to the groove 26 to be supplied uniformly throughout the whole circumference of the back surface of the wafer W.

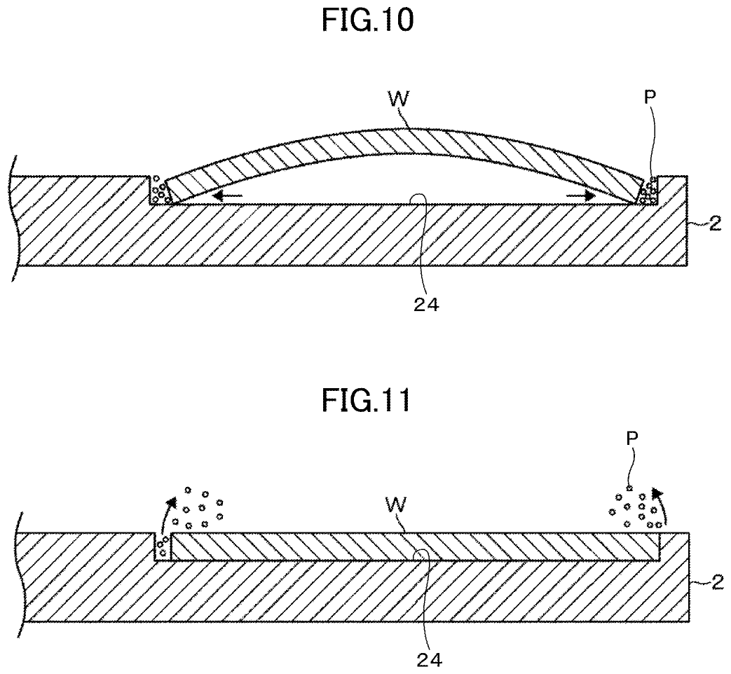

The reason why the groove 26 is formed between the inner wall surface of the recess 24 and the outer wall surface of the support 25 and the purge gas supply 28 that supplies the purge gas to the groove 26 is provided will be described with reference to FIGS. 10 to 14.

First, a case in which the wafer W is directly mounted on the bottom surface of the recess 24 without providing the support 25 will be described. If the unprocessed wafer W before being mounted on the susceptor 2 is at the ambient temperature, when the wafer W is mounted on the susceptor 2, a temperature variation is generated in the plane, and then the temperature rises toward the deposition temperature, and the temperature variation is reduced. With respect to the above, if another heat treatment has already been performed on the wafer W by a heat treatment apparatus other than the deposition apparatus, spontaneous heat radiation of the wafer W is performed during the transfer to the deposition apparatus, and the temperature drop rate at this time becomes non-uniform in the plane of the wafer W. Thus, if a heat treatment is performed on the wafer W in advance, when the wafer W is mounted on the susceptor 2, a temperature variation of the wafer W is already generated, and then the temperature variation gradually is reduced by the heat input from the susceptor 2.

Therefore, when the wafer W is mounted on the susceptor 2, the temperature variation is generated in the plane, regardless of whether the unprocessed wafer is at the ambient temperature or the heat treatment has already been performed on the wafer. At this time, based on the temperature variation of the wafer W, the wafer W may be curved in a shape of a mountain (convex upward). If the wafer W is curved in a shape of a mountain as described, the central portion of the wafer W is separated from the surface of the susceptor 2 and the circumferential edge portion of the wafer W comes into contact with the susceptor 2. Then, as illustrated in FIG. 10, when the wafer W is mounted directly on the bottom surface of the recess 24, the circumferential edge portion of the wafer W and the surface of the susceptor 2 (in particular, the bottom surface of the recess 24) rub against each other while the wafer W extends flatly as the temperature of the wafer W becomes uniform. As a result, particles P are generated. When the wafer W has extended flatly, for example, the particle P moves around the circumferential edge portion side of the wafer W and is adhered to the surface of the wafer W, as illustrated in FIG. 11. Thus, in order to minimize the number of particles P adhered on the surface of the wafer W, it is not preferable that the wafer W is directly mounted on the bottom surface of the recess 24.

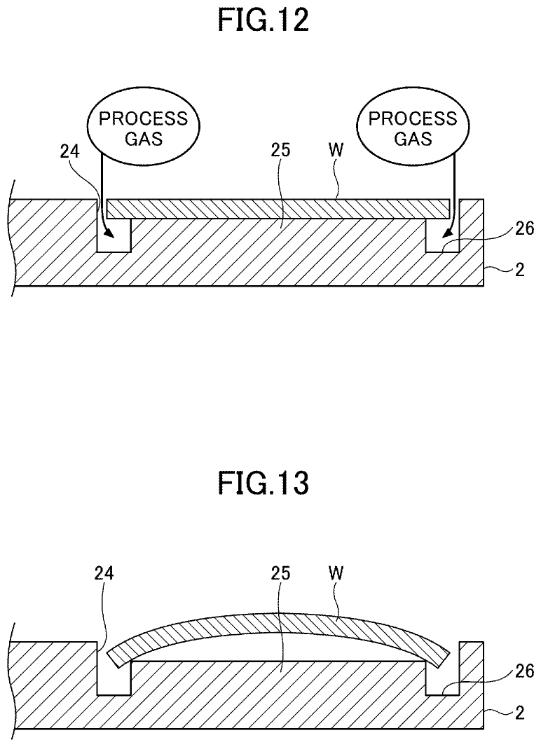

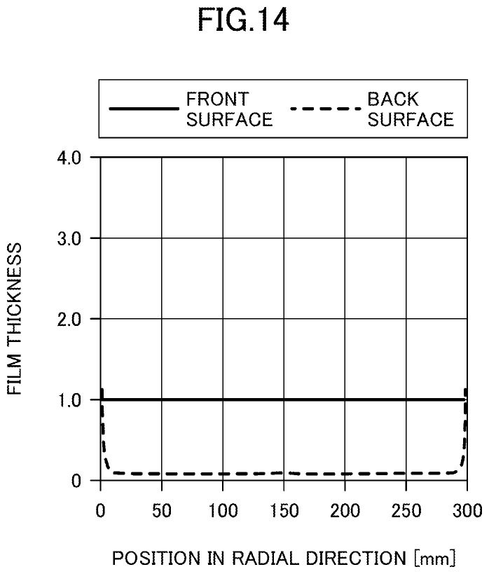

Therefore, as illustrated in FIG. 12 and FIG. 13, it is conceivable that by providing the support 25 on the bottom surface of the recess 24, the circumferential edge portion of the wafer W does not contact the bottom surface of the recess 24, thereby reducing the number of particles adhered on the surface of the wafer W. In this case, when the process gas is supplied to the wafer W to apply the deposition process, a portion of the process gas supplied to the circumferential edge portion of the wafer W may pass between the circumferential edge portion of the wafer W and the inner wall surface of the recess 24 and move to the back surface side of the wafer W, and a film may be deposited on the back surface edge portion of the wafer W. The film thickness of the film deposited on the back surface edge portion of the wafer W can be greater than or equal to the film thickness of the film deposited on the surface of the wafer W, as illustrated in FIG. 14, for example. Then, if the film thickness of the film deposited on the back surface edge portion of the wafer W becomes thick, peeling of the film occurs, and a particle is generated. In FIG. 14, the horizontal axis indicates a radial direction position of the wafer W having a diameter r of 300 mm, and the vertical axis indicates the film thickness of the film deposited on the back surface of the wafer W when the film thickness of the film deposited on the surface of the wafer W is assumed to be 1.

In the embodiment, the annular groove 26 is formed between the inner wall surface of the recess 24 and the outer wall surface of the support 25, and the purge gas supply 28 that supplies the purge gas to the groove 26 is provided. This allows the purge gas to be supplied to the groove 26 when the process gas is supplied to the surface of the susceptor 2 in a state where the wafer W is mounted on the support 25. The purge gas supplied to the groove 26 prevents the process gas from contacting the back surface edge portion of the wafer W, the inner wall surface of the groove 26, the bottom surface of the groove 26, and the like. Therefore, the deposition of the film on the back surface edge portion of the wafer W, the inner wall surface of the groove 26, the bottom surface of the groove 26, and the like is suppressed. As described above, in the embodiment, the generation of particle P due to the rubbing of the circumferential edge portion of the wafer W and the surface of the susceptor 2 can be suppressed, and the deposition of the film on the back surface edge portion of the wafer W, the inner wall surface of the groove 26, the bottom surface of the groove 26, and the like can be suppressed.

[Modified Example of a Susceptor Configuration]

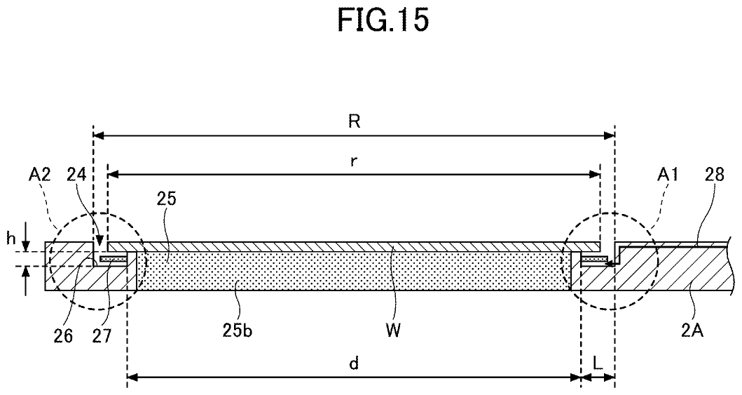

Another example of the susceptor of the deposition apparatus according to the embodiment will be described with reference to FIG. 15. A susceptor 2A illustrated in FIG. 15 differs from the susceptor 2 previously described in that the susceptor 2A includes a porous portion 25b communicating from a front surface to a back surface in a region including the support 25. Other configurations may be the same as in the configuration of the susceptor 2 previously described.

The porous portion 25b communicates from the front surface thereof to the back surface thereof in the region including the support 25. The porous portion 25b is formed such that the diameter of the porous portion 25b is smaller than the diameter of the wafer W in a plan view for example. The porous portion 25b may be fixed to the susceptor 2 and may be removable from the susceptor 2. If the porous portion 25b is removable from the susceptor 2, the porous portion 25b may be configured to rotate with respect to the susceptor 2. The porous portion 25b is formed of, for example, SiC, SiN, or the like that is the same material as the porous ring 27.

As described, by providing the porous portion 25b in the region including the support 25, the purge gas that enters between the upper surface of the support 25 and the back surface of the wafer W can be discharged below the susceptor 2A through the porous portion 25b when the wafer W is mounted on the support 25. This can suppress misalignment caused when the purge gas enters between the upper surface of the support 25 and the back surface of the wafer W mounted on the support 25.

<Deposition Method>

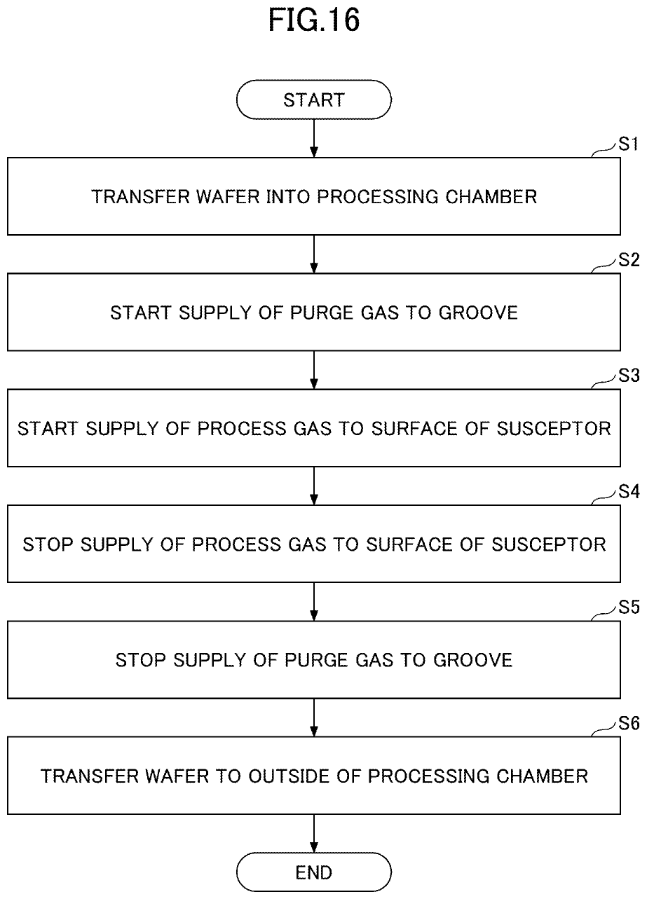

An example of a deposition method according to the embodiment will be described with reference to FIG. 16. In the following, an example in which a silicon oxide film (SiO₂ film) is deposited on the wafer W in the deposition apparatus described above will be described. Here, the following description assumes that the susceptor 2 has already been heated by the heater 7 so that the wafer W mounted on the susceptor 2 is heated to a deposition temperature (for example, about 300° C.)

First, the wafer W is transferred into the processing chamber 1 (step S1). In one embodiment, the gate valve G is opened, and while the susceptor 2 is intermittently rotated, five wafers W, for example, are mounted on the susceptor 2 through the transfer port 15 by the transfer arm (not illustrated). These wafers W are each mounted at the central position in the recess 24 and are therefore separated from (or are not contacted with) the inner wall surface of the recess 24 over the circumferential direction. At this time, the wafer W may be at the ambient temperature, or another heat treatment may be already applied to the wafer W, and when the wafer W is mounted on the susceptor 2, the wafer W may be curved in a shape of a mountain based on the temperature variation in the plane of the wafer W, as illustrated in FIG. 13.

The gate valve G is then closed and the processing chamber 1 is vacuumed by the vacuum pump 64, and the susceptor 2 rotates clockwise at 2 rpm to 240 rpm, for example. At this time, because the groove 26 is formed in the recess 24, the circumferential edge portion of the wafer W is separated from the surface of the susceptor 2 and the surface of the support 25 even when the wafer W is curved in a mountain shape, so that the generation of particles caused by sliding the circumferential edge portion against the support 25 is suppressed.

The supply of the purge gas to the groove 26 is then started (step S2). In one embodiment, the N₂ gas is discharged from the separation gas supply line 51 at a predetermined flow rate and the N₂ gas is supplied as the purge gas to the groove 26 through the purge gas supply 28.

The supply of the process gas to the surface of the susceptor 2 is then started (step S3). In one embodiment, the first process gas and the second process gas are respectively discharged from the first process gas nozzle 31 and the second process gas nozzle 32, and the plasma generation gas is discharged from the plasma generation gas nozzle 34. Additionally, the separation gas is discharged from the separation gas nozzles 41 and 42 at a predetermined flow rate, and the N₂ gas is discharged from the separation gas supply line 51 and the purge gas supply lines 72 and 72 at a predetermined flow rate. The inside of the processing chamber 1 is adjusted to a preset process pressure by the pressure adjuster 65, and the high-frequency power is supplied to the plasma generator 80.

At this time, each process gas supplied to the wafer W attempts to move around in the area on the back surface side of the wafer W through the clearance between the circumferential edge portion of the wafer W and the inner circumferential surface of the recess 24. However, because the purge gas is supplied to the groove 26, the movement of the process gas into the groove 26 is suppressed. This prevents the film from being deposited on the back surface edge portion of the wafer W, the inner wall surface of the groove 26, the bottom surface of the groove 26, and the like.

On the surface of the wafer W, the first process gas is adsorbed in the first process region P1 by the rotation of the susceptor 2, and the reaction between the first process gas adsorbed on the wafer W and the second process gas occurs in the second process region P2. This forms one or more molecular layers of silicon oxide film, which is a thin film component, on the surface of the wafer W to form a reaction product. At this time, the reaction product may contain impurities such as water (a hydroxyl group (OH)), organic matter, and the like, for example, due to the residue group contained in the first process gas.

On the lower side of the plasma generator 80, the electric field among the electric field and magnetic field generated by the high-frequency power supplied from the high-frequency power supply 85 is reflected or absorbed (attenuated) by the Faraday shield 95, thereby preventing (blocking) the arrival of the electric field into the processing chamber 1. The magnetic field passes through the slit 97 of the Faraday shield 95 and arrives into the processing chamber 1 through the bottom surface of the housing 90. Thus, the plasma generation gas discharged from the plasma generation gas nozzle 34 is activated by the magnetic field passing through the slit 97 to produce a plasma, such as an ion, a radical, or the like.

When the plasma (the active species) generated by the magnetic field contacts the surface of the wafer W, the modification treatment is performed on the reaction product. Specifically, by the plasma colliding with the surface of the wafer W, for example, the impurities are released from the reaction product, or the elements in the reaction product are rearranged to achieve densification. By continuing the rotation of the susceptor 2, the adsorption of the first process gas to the surface of the wafer W, the reaction of the component of the first process gas adsorbed to the surface of the wafer W, and the plasma modification of the reaction product are performed in this order and over many times, the reaction products are laminated to form a thin film.

Additionally, because the N₂ gas is supplied between the first process region P1 and the second process region P2, each gas is evacuated such that the first process gas, the second process gas, and the plasma generation gas do not mix with each other. Further, because the purge gas is supplied to the lower side of the susceptor 2, the gas to be diffused to the lower side of the susceptor 2 is pushed back to the exhaust ports 61 and 62 by the purge gas.

After the deposition process is completed, the supply of the process gas to the surface of the susceptor 2 is stopped (step S4). In one embodiment, the supply of the gas from each of the nozzles 31, 32, 34, 41, and 42 is stopped.

After stopping the supply of the process gas to the surface of the susceptor 2, the supply of the purge gas to the groove 26 is stopped (step S5). In one embodiment, the supply of the N₂ gas from the purge gas supply 28 to the groove 26 is stopped.

Subsequently, the wafer W is transferred to the outside of the processing chamber (step S6). In one embodiment, the rotation of the susceptor 2 is stopped. Then, the susceptor 2 is intermittently rotated to transfer the wafers W one by one through the transfer port 15. When all wafers W are transferred, one run (one rotation of the deposition process) is completed.

The embodiments disclosed herein should be considered to be examples and not restrictive in all respects. Omission, substitution, and modification can be made to the above embodiments in various forms without departing from the scope of the appended claims and spirit thereof.

What is claimed is:

1. A deposition apparatus comprising:
a processing chamber;
a susceptor provided in the processing chamber, the susceptor having a recess on a surface of the susceptor, the recess including a support and a groove, the support supporting a region that includes a center of a substrate and that does not include an edge of the substrate, the groove being located around the support, and the groove being recessed relative to the support;
a process gas supply configured to supply a process gas to the surface of the susceptor; and
a purge gas supply configured to supply a purge gas to the groove.

2. The deposition apparatus as claimed in claim 1, further comprising a porous ring provided around the support between a back surface of the substrate supported by the support and a bottom surface of the groove.

3. The deposition apparatus as claimed in claim 2, wherein the porous ring is provided to form a clearance between an inner wall surface of the recess and the porous ring.

4. The deposition apparatus as claimed in claim 2, wherein the purge gas supply supplies the purge gas between the bottom surface of the groove and a back surface of the porous ring.

5. The deposition apparatus as claimed in claim 2, wherein the porous ring is formed of SiC.

6. The deposition apparatus as claimed in claim 1,
wherein the recess further includes a protrusion portion that is provided along the groove and that protrudes from a bottom surface of the groove.

7. The deposition apparatus as claimed in claim 1, wherein the susceptor includes a porous portion that communicates from a front surface of the porous portion to a back surface of the porous portion in a region including the support.

8. The deposition apparatus as claimed in claim 1,
wherein the substrate has a circular plate shape, and
wherein the recess has a circular shape, and a diameter of the recess is greater than a diameter of the substrate.

9. A deposition method that performs processing on a substrate in a deposition apparatus including a susceptor provided in a processing chamber, the susceptor having a recess on a surface of the susceptor, the recess including a support and a groove, the support supporting a region that includes a center of the substrate and that does not include an edge of the substrate, the groove being located around the support, and the groove being recessed relative to the support, the deposition method comprising:
starting supply of a purge gas to the groove in a state where the substrate is supported by the support;
supplying a process gas to the surface of the susceptor in a state where the purge gas is supplied to the groove;
stopping the supplying of the process gas; and
stopping the supply of the purge gas after stopping the supplying of the process gas.
